(19) United States
(12) Patent Application Publication
(10) Pub. No.: US 2002/0004323 A1
(43) Pub. Date: Jan. 10, 2002

(54) Right-angle type electrical connector

(76) Inventor: Yumiko Azuma, Tokyo (JP)

Correspondence Address: ROBERT W. J. USHER, PATENT AGENT, 1133 BROADWAY, #1515, NEW YORK, NY, 10010

(21) Appl. No.: 09/897,663

(22) Filed: Jul. 2, 2001

(30) Foreign Application Priority Data
Jul. 4, 2000 (JP) 2000-202108

(51) Int. Cl. H05K 1/00

(52) U.S. Cl. 439/79

(57) ABSTRACT

A right-angle type electrical connector 1 comprises a housing 10 which includes a fitting part 11 and a mount bottom surface 13. The fitting part 11 is located at the front of the housing and is used for engaging with a matable connector, and the mount bottom surface 13 is to be placed on a circuit board. A plurality of electrical contacts 31 and 32 are aligned laterally and retained in the housing 10. These contacts extend rearward beyond the fitting part 11 and are soldered to a circuit provided on the circuit board. The housing further includes foot portions 15c which extend rearward beyond the soldered parts of the contacts 31 and 32. The mount bottom surface 13, which also extends to the rear ends of the foot portions 15c, is positioned at a higher level than the bottom surface 11a of the fitting part 11, with a step 14 provided therebetween. With this step 14, the right-angle type electrical connector faces the edge E of the circuit board.

### FIELD OF THE INVENTION

The present invention relates to a so-called right-angle type electrical connector which is fixed on a printed circuit board and is engaged with a matable electrical connector oriented in a direction parallel to the printed circuit board.

### BACKGROUND OF THE INVENTION

Such right-angle type electrical connectors have been used widely as a connector for coupling a circuit board to another circuit board (B to B) or as a connector for connecting a circuit board to electrical wires (B to W). For example, if one of the two circuit boards is provided with a male right-angle type electrical connector while the other is provided with a female right-angle type electrical connector, then these two circuit boards can be coupled in parallel with each other for electrical signal communication. On the other hand, if one is provided with a right-angle type electrical connector while the other is provided with a straight-type connector, then these two circuit boards can be coupled perpendicular to each other. Moreover, if a circuit board is provided with a right-angle type electrical connector, then a straight or cross cable can be used to connect an electrical device to electrical components which are mounted on the circuit board.

A right-angle type electrical connector comprises a housing (also referred to as “insulator”), which is to be mounted on a circuit board, and a plurality of electrical contacts, which are aligned in laterally extending lines and retained in the housing. The front portion of the housing includes a fitting part which is used for engagement and disengagement with a matable connector, which is oriented parallel to the circuit board and translated in a front and rear direction. In the fitting part, the contact portions of the electrical contacts extend in the front and rear direction, such that when the right-angle type electrical connector is engaged with a matable connector, the contact portions of the right-angle type electrical connector come into contact with the contact portions of the matable connector. Each contact of the right-angle type electrical connector is fitted tightly in the housing at a retained portion which is located immediately next to the contact portion rearward and then bent toward the circuit board at the rear of the housing. For mounting the right-angle type electrical connector, the housing is fixed on the circuit board, for example, with metal hooks, and the tail portions or lead portions of the contacts, which are bent toward the circuit board, are then soldered onto terminals of a circuit which is provided in a pattern on the circuit board.

If such a right-angle type electrical connector were mounted on a circuit board without any auxiliaries, then forces applied for engaging and disengaging a matable connector could damage the right-angle type electrical connector at the portions where the contacts are soldered to the circuit board. To avoid such a shearing strain and a resultant damage, various methods are considered and practiced for the purpose of making the forces applied for the engagement and disengagement of a matable connector not to act directly onto these soldered portions. For example, holes are provided through the circuit board at predetermined positions, and resilient metallic hooks are inserted into these through-holes and locked therein to fix the housing of the connector, or cylindrical bosses are provided on the housing and are fitted in the through-holes of the circuit board to receive the thrust generated during the engagement and disengagement of a matable connector. Another method is to provide threaded holes in the housing, and screws are used to fix the connector on the circuit board.

However, the engagement and disengagement of a matable connector to the right-angle type electrical connector is executed in the front and rear direction that is parallel to the circuit board as described above, and the fitting part of the right-angle type electrical connector, which receives the counterpart of the matable connector, is located away and above the circuit board. Because of these factors, when the connectors are engaged and disengaged, the right-angle type electrical connector receives not only a thrust which acts parallel to the circuit board but also a moment whose magnitude corresponds to the vertical offset that is the distance from the circuit board to the axis of engagement, which passes through the fitting part. For example, when a matable connector is brought into engagement with a prior-art right-angle type electrical connector, whose sectional side view is shown in FIG. 4, a thrust F₁ applied for the insertion of a matable connector produces a clockwise moment M₁ around the rear end P₁ of the housing, the moment acting to raise the fitting part of the connector.

As a result, for example, a right-angle type electrical connector which is fixed on a circuit board by a method where cylindrical bosses of the housing are fitted in through-holes of the circuit board is not effective for withstanding such a moment. As a result, there has been a problem of the connector being detached or raised from the circuit board by the actions of engaging and disengaging a matable connector. In a right-angle type electrical connector which is fixed on a circuit board by a method where metallic hooks are used to lock and fix the connector, this problem is somewhat alleviated. However, when a matable connector is brought into engagement with this right-angle type electrical connector, the moment produced by a thrust used for the coupling acts to pull out the metallic hooks. The magnitude of this pullout force f₁ equals the moment M₁ divided by the distance l₁ from the reference point P₁ of the moment to the metallic hooks. It is a current trend to design this distance l₁ as short as possible only to keep a dimension necessary for retaining the contacts. The reason is the recent demand for minimizing the area which is occupied by the connector on the circuit board. As a result, the pull-out force f₁ tends to become inevitably large. It is difficult for the metallic hooks to resist this pull-out force f₁ only by their resiliency. Thus, there is a possibility that the connector may be detached or raised from the circuit board. On the other hand, a right-angle type electrical connector whose housing is fixed on a circuit board with screws is not prone to be detached from the circuit board because the threaded parts of the connector can resist the pulling force of such a moment, so the contacts of the connector is protected from deformation, which may occur if the connector is detached and raised from the circuit board. However, this method of fixing the connector with screws increases the number of parts and processing steps in the production of right-angle type electrical connectors and thereby decreases the production efficiency.

### SUMMARY OF THE INVENTION

It is an object of this invention to provide a right-angle type electrical connector whose long-term reliability is improved, without sacrificing production efficiency, by preventing the above described problem, i.e., the detachment of the housing of the connector from the circuit board caused from a moment which is produced when a matable connector is engaged.

A right-angle type electrical connector according to the present invention comprises a housing and a plurality of electrical contacts. The housing extends laterally and includes a fitting part at the front thereof and a mount bottom surface at the lower end thereof. The fitting part is engageable with a matable connector (for example, the plug connector 5 of the embodiment described in the following section), and the bottom surface is to be placed on a surface of a circuit board for fixing the housing of the connector on the circuit board. The electrical contacts are aligned laterally and retained in the housing, with one end of each contact being positioned at the fitting part and to be brought into contact with a corresponding contact of the matable connector and the other end being positioned behind the fitting part and to be connected and fixed to a circuit provided on the circuit board. This right-angle type electrical connector is engageable through the fitting part with the matable connector in a front and rear direction that is parallel to the circuit board. Furthermore, the housing of the right-angle type electrical connector further includes a foot portion that extends rearward beyond the connecting portions of the electrical contacts, which portions are to be connected to the circuit board, and the mount bottom surface of the housing extends to the rear end of the foot portion.

Because the housing of the right-angle type electrical connector has the foot portion, which extends rearward beyond the portions of the electrical contacts connecting to the circuit board, and because the mount bottom surface of the housing, which is supported on the circuit board, extends to the foot portion, the elongated foot portion can maintain the housing against the moment produced while the matable connector is being brought into engagement with the right-angle type connector. Because the foot portion includes an extension to the mount bottom surface, i.e., the foot portion functions as the rearward extension of the housing, an extension is provided to the distance between the reference point of the moment produced during the coupling of the connectors and the location of the fixing means such as the metallic hooks and the contacts used for fixing the right-angle type electrical connector on the circuit board. Therefore, the pulling force of the moment that acts on the metallic hooks and the contacts is restrained to a relatively small size. In addition, with the elongated foot portion, the reference point of the moment is located far to the rear end of the housing, so the inclination of the housing on the circuit board can be also restrained to a minimal size. In this way, without applying such tightening means as screws, the present invention provides the right-angle type electrical connector with this structural protection against the above described moment, which acts to detach and raise the connector from the circuit board during the mating of the connectors. As a result, the right-angle type electrical connector achieves an improved long term reliability without affecting productivity.

Preferably, the mount bottom surface of the housing of the right-angle type electrical connector should be provided at a higher level than the lower surface of the fitting part of the housing, and a step (the step that includes the upstanding surface 14, described in the following embodiment) should be provided between the lower surface of the fitting part and the mount bottom surface. This means that the right-angle type electrical connector can acquire, for its axis of engagement, a relatively low height from the mount bottom surface of the housing. In other words, the right-angle type electrical connector can have a relatively short distance from the reference point of the resultant moment to the location where a thrust is generated while the matable connector is being brought into engagement or disengagement. Therefore, the moment that is produced on the right-angle type electrical connector while the connectors are brought into engagement and disengagement itself is restrained to a relatively small size. Furthermore, because the step of the housing is placed to face the edge of the circuit board, the thrust generated during the coupling of the connectors is received by the edge of the circuit board. In this way, the above described advantages of the right-angle type electrical connector are further advanced to improve the long term reliability of the right-angle type electrical connector.

It is also preferable that the step of the right-angle type electrical connector be positioned below the contact-retaining portion of the housing which retains the contacts tightly. When the step is positioned below the contact-retaining portion, the step is located rearward behind the fitting part of the housing. With this construction, the right-angle type electrical connector can achieve a relatively low height for the axis of engagement above the circuit board while a required strength is still secured for the right-angle type electrical connector because no reduction is made in the thickness of the wall of the fitting part or no cut-out is necessary in the matable connector.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only and thus are not limitative of the present invention and where in:

FIGS. 1(a), 1(b) and 1(c) are a top view, a front view and a bottom view of a right-angle type electrical connector according to the present invention.

FIG. 2 is a sectional side view of the connector, taken along line II-II in FIG. 1(b).

FIG. 3 is a sectional side view of the connector, which is mounted on a circuit board, and a sectional side view of a matable connector, which is brought into engagement with the right-angle type electrical connector.

FIG. 4 is a sectional side view of a prior-art right-angle type electrical connector.

### DESCRIPTION OF THE PREFERRED EMBODIMENTS

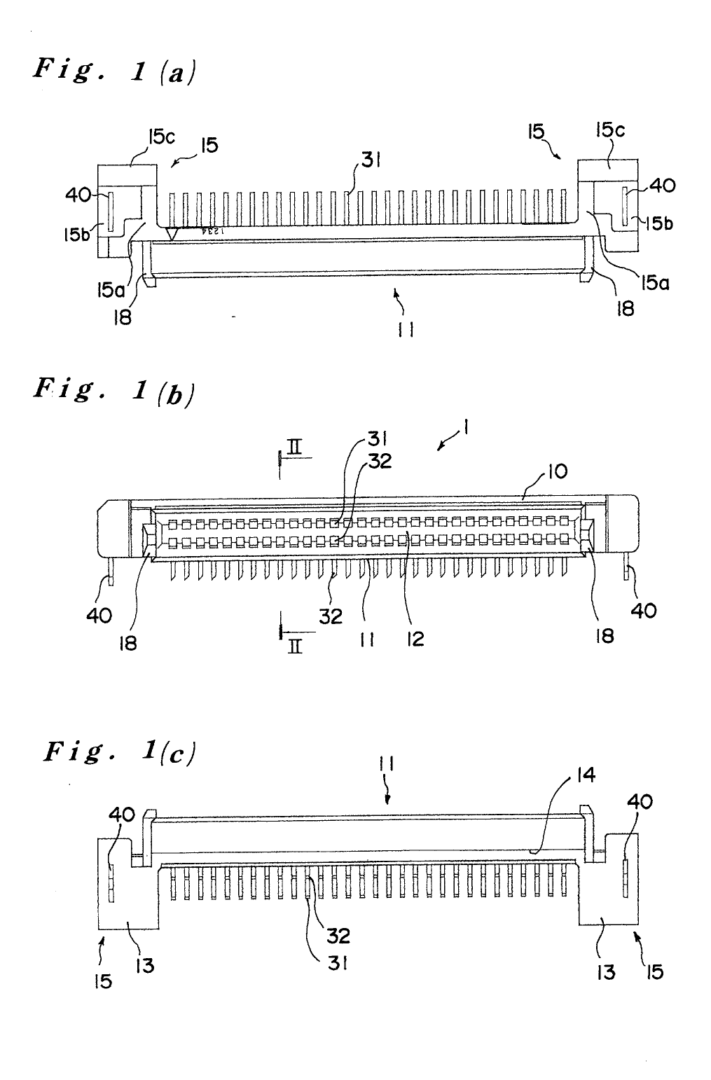

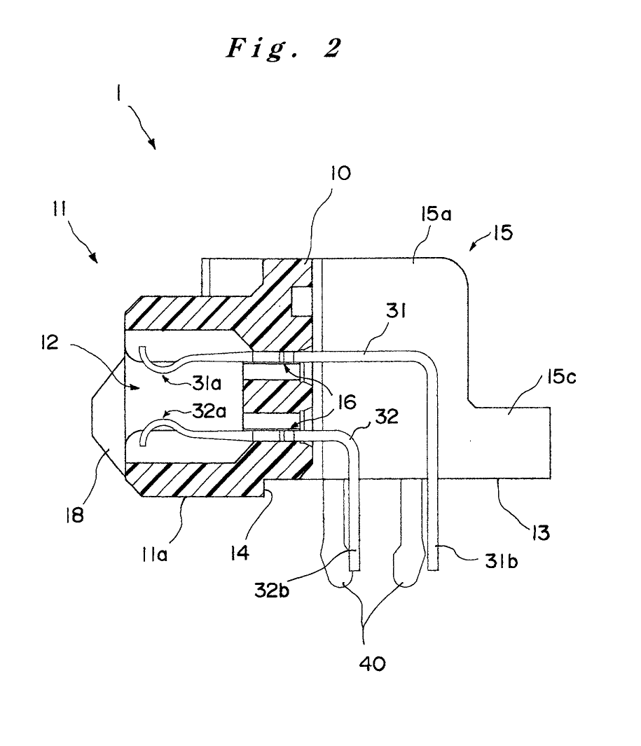

Now, a preferred embodiment of the present invention is described in reference to the drawings. FIG. 1 shows a multielectrode receptacle connector (hereinafter referred to as the “receptacle”) 1 as an embodiment of right-angle type electrical connector according to the present invention. This receptacle 1 is designed to be mounted on a through-hole type printed circuit board (hereinafter referred to as the “circuit board”). FIGS. 1(a), 1(b) and 1(c) are a top view, a front view and a bottom view, respectively, of the receptacle 1, and FIG. 2 is a main sectional view of the receptacle 1, taken along line II-II in FIG. 1(b).

The receptacle 1 comprises a housing 10 and a plurality of metallic contacts 31 and 32, and metallic hooks 40. The housing 10 is formed from an insulative resin such as polyphenylene sulfide (PPS) which is reinforced, for example, with chopped strands of glass fibers. The metallic contacts 31 and 32 are retained in alignment in the housing 10 and are used for signal transmission, and the metallic hooks 40 are press-fit in the housing 10 and are used for fixing the receptacle 1 on the circuit board.

The housing 10 has a mount bottom surface 13 at the lowest part thereof. For mounting the receptacle 1, the mount bottom surface 13 of the receptacle 1 is placed on the circuit board, and the receptacle 1 is fixed thereon with the metallic hooks 40. In this mounted condition, a fitting part 11 which is provided at the front of the receptacle 1 protrudes forward (in FIG. 1(b), in the direction that is normal to the paper which carries the drawings) and is ready to be engaged and disengaged with a matable plug connector in the front and rear direction.

The fitting part 11 of the housing 10 includes a receiving room 12 that is open forward to receive the plug connector, which is inserted therein by the translation of the plug connector from the front side of the receptacle 1 in the rear direction. In the receiving room 12, a plurality of upper contacts 31 and lower contacts 32 are aligned and retained, each group of contacts laterally and each upper contact opposing a corresponding lower one vertically. The fitting part 11 further includes guides 18 at the lateral ends thereof, and the guides 18 are to facilitate the positioning of the plug connector for the insertion.

The contacts 31 and 32 are fabricated from a thin resilient metal plate by die-punching and by press molding to have the respective shapes shown in FIG. 2 in side view. The contacts 31 and 32 are press-fit from the rear side of the housing 10 into slot-like contact-retaining portions 16 that are provided at the innermost part of the receiving room 12 of the housing 10, so the contacts 31 and 32 are retained and fixed therein.

The front portions of the upper contacts 31 and lower contacts 32 are formed as levers protruding from the contact-retaining portions 16 into the receiving room 12 and are resilient to undergo elastic deformation upward and downward, respectively. Semi-cylindrical contact portions 31a and 32a are provided at the front ends of the upper contacts 31 and lower contacts 32, respectively, with the semi-cylindrical contact portion 31a of each upper contact 31 facing the semi-cylindrical contact portion 32a of a corresponding lower contact 32 in a vertical plane. On the other hand, the other sides of the contacts 31 and 32 beyond the contact-retaining portions 16 are formed in square pillars and are bent downward at a predetermined distance away from the contact-retaining portions 16. At the lower ends of the contacts 31 and 32 provided are tail portions 31b and 32b, which are placed in and soldered to through-holes provided on the circuit board.

The housing 10 is open laterally widely at the rear part thereof behind the contact-retaining portions 16 to expose the contacts 31 and 32, and the housing 10 includes lateral anchoring portions 15, which are formed to connect the fitting part 11 and the contact-retaining portions 16 as a one-body housing. Each anchoring portion 15 comprises a rib-like rising portion 15a, a hook-retaining portion 15b, which retains a metallic hook, and a foot portion 15c, which extends rearward from the rising portion 15a and the hook-retaining portion 15b.

As shown in FIG. 2, the rising portions 15a protect the upper contacts 31 and the lower contacts 32, which are bent in “L” shapes, from the right and left sides. The hook-retaining portions 15b have half the height of the rising portions 15a. In the hook-retaining portions 15b, press-fit and fixed are the metallic hooks 40, each of which is formed from a thin metal plate into a “U” shape by die-punching. The metallic hooks 40 are fixed in the housing 10 with resiliency in the front and rear direction as shown in the drawing, so the two arms of each metallic hook 40 protrude downward from a corresponding hook-retaining portion 15b.

The foot portions 15c, each of which resembles a flange, extend rearward from the respective rising portions 15a and hook-retaining portions 15b beyond the tail portions 31b of the upper contacts 31, which are positioned rearward with respect to the lower contacts 32.

In the design of the housing 10, the fitting part 11 is positioned such that the height of the axis of engagement for a matable connector, which passes through the fitting part 11, is lower than half the height of the housing 10. As a result, the bottom surface 11a of the fitting part 11 is lower than the mount bottom surface 13 of the housing 10, and an upstanding surface 14 is created at the location immediately below the contact-retaining portions 16, perpendicularly to these two surfaces, the upstanding surface 14 stepping up vertically the bottom surface 11a of the fitting part 11 to the mount bottom surface 13, which extends to the foot portions 15c located at the rear end of the housing 10. Thus, the receptacle 1 has its axis of engagement at a relatively low level, and at the same time, a sufficient thickness for the lower wall of the receiving room 12 to maintain a required strength for the fitting part 11.

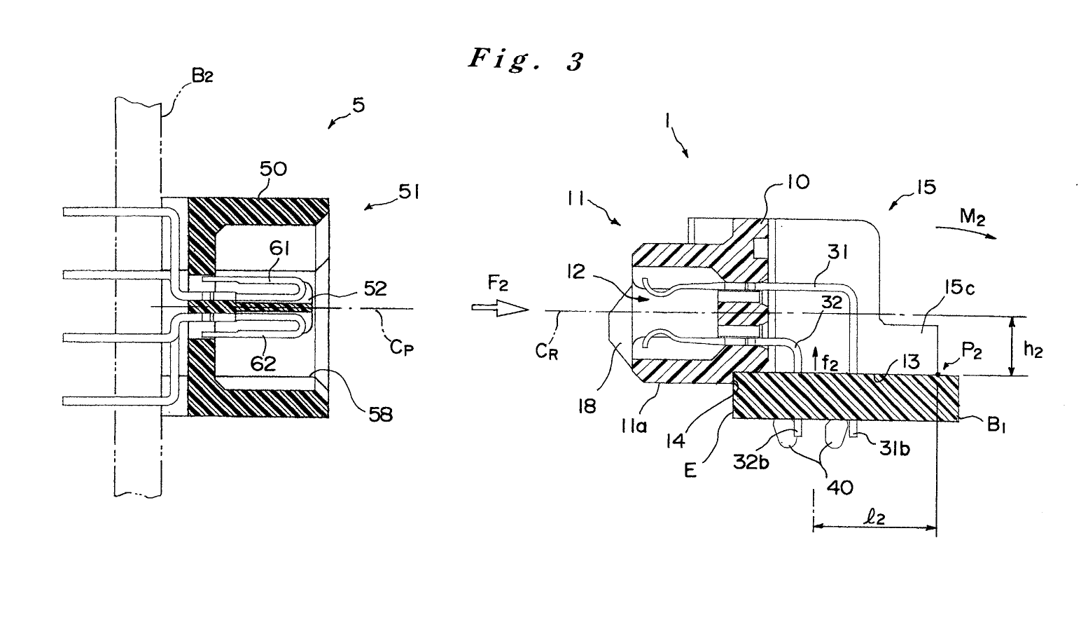

As shown in FIG. 3, the receptacle 1 is mounted on the circuit board B₁, on which circuits are printed in a pattern. The circuit board B₁ includes anchoring holes with a predetermined diameter at predetermined positions for the insertion of the metallic hooks 40 of the receptacle 1. For mounting the receptacle 1 on the circuit board B₁, the tail portions 31b and 32b of the contacts of the receptacle 1 are inserted into corresponding through-holes of the circuit board B₁, and the leading ends of the metallic hooks 40 of the receptacle 1 are placed to the anchoring holes of the circuit board B₁, and then the receptacle 1 is pressed downward. This pushing force makes the metallic hooks 40 to engage the anchoring holes, thereby locking the receptacle 1 on the circuit board B₁.

In this condition, the whole of the mount bottom surface 13 of the housing 10, from the front end below the fitting part 11 to the rear end of the anchoring portion 15, is in contact with the upper surface of the circuit board B₁, and the upstanding surface 14, i.e., the stepped part of the bottom of the housing 10, is in contact with an edge surface E of the circuit board B₁. When electronic parts mounted on the circuit board B₁ are soldered, for example, by a reflow soldering machine, the tail portions 31b and 32b of the contacts of the receptacle 1 are soldered together to fix the receptacle 1 on the circuit board B₁.

As an example of connector matable with the receptacle 1, a straight type multielectrode plug connector (hereinafter referred to as the “plug”) 5, which is mountable on a through-hole type printed circuit board B₂, is shown on the left side of the drawing in FIG. 3. The plug 5 is a male connector which is matable with the receptacle 1 and has the same number of electrodes as the receptacle 1. The plug 5 comprises a plug housing 50, whose fitting part 51 includes a protruding portion 52 in a closed-end space. On the upper and lower sides of the protruding portion 52, plug contacts 61 and 62 are aligned laterally and retained with the same pitch as the contacts 31 and 32 of the receptacle 1. Furthermore, at the right and left ends of the closed-end space, the plug housing 50 includes guide grooves 58, which are to receive the guides 18 of the receptacle 1.

The guides 18 and the guide grooves 58 are used for aligning the axes of engagement C_{R} and C_{P} of the receptacle 1 and the plug 5, respectively. Upon the alignment, the plug 5 is pushed into the receptacle 1 for engagement. In this instance, the protruding portion 52 of the plug 5 is inserted into the receiving room 12 of the receptacle 1, and the upper contacts 31 and 61 and the lower contacts 32 and 62 of the receptacle 1 and the plug 5 are brought into contact in pairs. When each pair of the contacts are in contact with each other, a pressure which is appropriate for securing electrical connection is generated by the resiliency of each contact experiencing a mutual elastic deformation. In this engaged condition, electrical signals can be communicated between these two circuit boards B₁ and B₂.

While the plug 5 is being pushed and inserted into the receptacle 1, a thrust F₂ is generated. The thrust F₂ acts on the receptacle 1 along the axis of engagement C_{R}, which is above the surface of the circuit board by height h₂. As a result, a moment is produced from the thrust F₂ on the receptacle 1.

Because of the construction of the receptacle 1 according to the present invention, in which the step, i.e., the upstanding surface 14, is provided on the bottom of the housing 10, the upstanding surface 14 is in contact with the edge E of the circuit board. In this condition, as the thrust F₂ acting on the receptacle 1 is received by the upstanding surface 14 and the edge E, the thrust F₂ does not act directly on the soldered parts between the contacts 31 and 32 and the circuit board.

Moreover, because the receptacle 1 is mounted on the circuit board with the step of the housing 10 engaged with the edge of the circuit board, the step of the housing 10 provides a reference point for another moment that acts on the receptacle 1. The moment around the step acts (in the direction where the force of the moment presses the mount bottom surface 13) oppositely against the moment M₂ which is produced around the rear end P₂ of the housing 10. As a result, the effect of the moment M₂, which acts in the direction where the force of the moment raises the fitting part 11, is reduced.

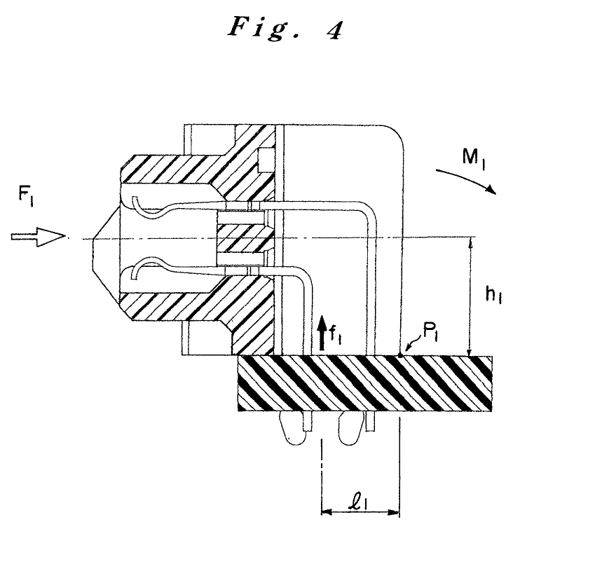

Furthermore, in the receptacle 1 according to the present invention, the mount bottom surface 13 of the housing 10 is positioned above the bottom surface 11a of the fitting part 11 by providing the above described step, so the height h₂ above the circuit board of the axis of engagement C_{R}, along which the thrust F₂ acts, is made lower than the height h₁ of the prior-art connector shown in FIG. 4. This means that the distance from the reference point of the moment which is produced by the thrust F₂ is shorter than that of the prior-art connector. In other words, the moment produced by the thrust F₂ itself is smaller in the receptacle 1 of the present invention. Even if the step provided next to the mount bottom surface 13 of the housing 10 is not contact with the edge of the circuit board, the moment M₂ (M₂=F₂×h₂) is smaller in the receptacle 1 according to the present invention than in the prior-art connector because the distance h₂ from the reference point is shorter in the receptacle 1 than the distance h₁ in the prior-art connector (refer to FIG. 4, and compare the cases).

In addition to this advantage of a reduced size of the moment M₂, the receptacle 1 according to the present invention has another advantage. Because the receptacle 1 has the foot portion 15c, the reference point P₂ around which the receptacle 1 is urged to rotate clockwise in FIG. 3 is located farther rearward in the receptacle 1 according to the present invention than in the prior-art connector. This means that if the same moment M₂ is produced for the receptacle 1 and for the prior-art connector, then the force f₂ pulling the metallic hooks 40 and the tail portions 31b and 32b of the contacts upward in the receptacle 1 is substantially smaller than that in the prior-art connector because the distance l₂ from the reference point in the receptacle 1 is longer than the distance l₁ in the prior-art connector (f₂=M₂/l₂, l₂>l₁; refer to FIG. 4 and compare the cases).

As described above, the receptacle 1 according to the present invention has achieved a relatively low height for the axis of engagement with a matable connector by providing a step at the bottom of the housing. It also has succeeded in restraining the pulling force generated on the receptacle 1 to a relatively low level by engaging the step to the edge of the circuit board and by providing the foot portions 15c to the housing to move the reference point of the moment farther rearward. Thus, the receptacle 1 according to the present invention achieves an effective prevention against the rising of the receptacle 1 away from the circuit board.

In the above embodiment, the flange-like foot portions 15c, which extend rearward beyond the contacts, have a height that is lower than those of the rising portions 15a and the hook-retaining portions 15b. However, it is not necessary for the foot portions to be formed in a flange-like figure. The foot portions may have the same height as the rising portions 15a and hook-retaining portions 15b. In the above embodiment, the right-angle type electrical connector according to the present invention is presented as a receptacle connector, which is mounted on a through-hole type printed circuit board. However, the present invention is not limited to this type of connector. The present invention can be applied similarly to a receptacle connector which is surface-mounted on a printed circuit board or to a plug connector, which is the other member of a pair of matable connectors. Furthermore, the matable connector which is engaged with the right-angle type electrical connector of the present invention is not limited to a straight type connector which is mounted on a circuit board. The matable connector may be also a similar right-angle type electrical connector or a cable connector.

As described above, the right-angle type electrical connector according to the present invention comprises a housing which extends laterally and includes a fitting part at the front thereof and a mount bottom surface at the lower end thereof, the bottom surface to be placed on a circuit board for mounting the connector. The right-angle type electrical connector further comprises a plurality of contacts which are aligned laterally and retained in the housing, one end of each contact being positioned in the fitting part and to be brought into contact with a corresponding contact of a matable connector and the other end being positioned at the rear of the housing behind the fitting part and to be connected and fixed to a corresponding terminal of a circuit provided on the circuit board. The right-angle type electrical connector having this construction engages through the fitting part with the matable connector, which is translated in the front and rear direction that is parallel to the circuit board. In this right-angle type electrical connector, it is a feature of the present invention that the housing includes foot portions, each of which extends rearward beyond the connections of the contacts to the terminals of the circuit board, with the mount bottom surface extending to the rear ends of the foot portions.

In this right-angle type electrical connector, the foot portions extending rearward can maintain the housing against a moment which is produced during the connection of the matable connector. Because of the construction of the right-angle type electrical connector, the reference point of the moment, which matches the rear ends of the foot portions, is located far rearward. As a result, the pulling force that acts on the metallic hooks and the contacts is relatively small. Therefore, the present invention reduces substantially the possibility of the right-angle type electrical connector rising away from the circuit board. Because the present invention does not apply such tightening means as screws, it can provide the right-angle type electrical connector with improved long term reliability without any adverse effect on productivity.

As the housing of the right-angle type electrical connector has a step provided between the bottom surface of the fitting part and the mount bottom surface, which is provided at a level higher than the bottom surface of the fitting part, the size of the moment produced while the matable connector is being brought into engagement is relatively small. Because the step provided between the bottom surface of the fitting part and the mount bottom surface of the housing faces the edge of the circuit board, the thrust generated while the matable connector is being brought into engagement is received by the edge of the circuit board. Furthermore, because the step provides a reference point for another moment which acts against the moment produced by the thrust of the coupling, the size of the moment affecting the right-angle type electrical connector is relatively small. In this way, the present invention can provide the right-angle type electrical connector with further improved long term reliability in addition to the previously described advantages.

Furthermore, as the above described step of the housing is provided below the contact-retaining portions of the housing where the contacts are retained tightly, the fitting part of the housing can have a sufficient thickness. Therefore, the present invention secures a sufficient strength for the right-angle type electrical connector and further improves the long term reliability.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### RELATED APPLICATIONS

This application claims the priority of Japanese Patent Application No. 2000-202108 filed on Jul. 4, 2000, which is incorporated herein by reference.

What is claimed is:

1. A right-angle type electrical connector comprising:
a housing which extends laterally and includes a fitting part at a front thereof and a mount bottom surface at a lower end thereof, said fitting part being engageable with a matable connector and said bottom surface to be placed on a surface of a circuit board for fixing said housing on said circuit board; and
a plurality of electrical contacts, which are aligned laterally and retained in said housing, an end of each contact being positioned at said fitting part and to be brought into contact with a corresponding contact of said matable connector and another end being positioned behind said fitting part and to be connected and fixed to a circuit provided on said circuit board;
said right-angle type electrical connector being engageable through said fitting part with said matable connector in a front and rear direction that is parallel to said circuit board;
wherein:
said housing includes a foot portion which extends rearward beyond connecting portions of said electrical contacts, said connecting portions to be connected to said circuit board, and
said mount bottom surface extends to a rear end of said foot portion.

2. The right-angle type electrical connector as set forth in claim 1, wherein said mount bottom surface of said housing is proved at a higher level than a lower surface of said fitting part of said housing, and a step is provided between said lower surface of said fitting part and said mount bottom surface.

3. The right-angle type electrical connector as set forth in claim 2, wherein said step is positioned below a contact-retaining portion of said housing, in which contact-retaining portion said contacts are retained tightly.
